(19) United States
(12) Patent Application Publication
(10) Pub. No.: US 2022/0069150 A1
(43) Pub. Date: Mar. 3, 2022

(54) NON-CONTACTING THICK-FILM BUSBAR PASTES FOR CRYSTALLINE SILICON SOLAR CELL EMITTER SURFACES

(71) Applicant: Jiangxi Jiayin Science and Technology, Ltd., Jiangxi (CN)

(72) Inventors: Meijun LU, San Jose, CA (US); Kurt R. MIKESKA, Hockessin, DE (US); Yawen XU, Jiangxi Province (CN); Baiqiang LIU, Henan Province (CN); Feibiao CHEN, Nanchang (CN); Xianqing XIE, Henan Province (CN)

(21) Appl. No.: 17/008,455

(22) Filed: Aug. 31, 2020

(51) Int. Cl. H01L 31/05

(52) U.S. Cl. CPC H01L 31/0512; H01L 31/0516

(57) ABSTRACT

Devices, methods, and systems are described for thick-film, screen-printable paste with inorganic frit for printing floating, non-contacting busbar line electrodes. Paste may be applied to crystalline solar cell emitter surfaces. The frit system contains both bismuth and boron. The described non-contacting busbar paste has superior solar cell performance compared to single-print conductor pastes.

### BACKGROUND OF THE INVENTION

### 1. Field of the Invention

The present invention relates generally to the manufacture of photovoltaic solar cells, and more importantly, to an electro-conductive thick-film, screen-printable paste for printing floating, non-contacting busbar line electrodes on crystalline silicon solar cell emitter surfaces.

### 2. Background

A photovoltaic (PV) solar cell is generally a semiconductor device that converts solar energy into electrical energy, and has been recognized as an infinite, clean, renewable next-generation energy source. PV solar cells generate direct electrical current, which flows to an external electrical circuit load through electrodes, or electrically conductive metallization lines. Crystalline silicon PV solar cell conductor metallizations based on silver thick-film, front-contact screen-printing techniques are common in the crystalline silicon solar cell industry because of their low cost, high throughput, and relatively high performance.

Current industrial scale screen-printed, phosphorus-doped n-type emitter, front junction p-type multi-crystalline silicon solar cells have efficiencies of approximately 18.9%. Current p-type mono-crystalline silicon solar cells have efficiencies of approximately 20.0%. Recent improvements in conductor metallizations have enabled the solar cell industry to commercialize advanced, high efficiency cell architectures, such as PERC (passivated emitter rear cell), PERT (passivated emitter rear totally diffused) and PERL (passivated emitter rear locally-diffused) designs, which have resulted in a steady incremental increase in solar cell efficiency.

Industrial crystalline solar cell manufactures may apply front-side screen-printable pastes by a single-print screen-print process. To further improve solar cell efficiency, a dual-print screen-print process may be utilized.

A single-print process may use one screen to print both the conductor metallization finger lines and busbar metallization lines in a single print sequence using one screen-printable paste. In this case, the paste makes electrical contact to the underlaying emitter layer beneath both the conductor finger lines and busbar lines. Typical final conductor line widths are about 35 μm (0.035 mm) and busbar line widths about 800 μm (0.8 mm).

A dual-print process may be utilized to decouple the front-side conductor metallization finger lines from the busbar metallization lines. For a typical dual-print process, two screen-printable pastes, each with a different composition, are typically printed in two separate print sequences using two separate print screens. The first screen-print sequence utilizes a paste for printing non-contacting, floating busbar lines. The second print sequence utilizes a paste for printing contacting conductor finger lines. Typical final conductor finger line widths are about 35 μm (0.035 mm) and busbar line widths about 800 μm (0.8 mm).

In a dual-print process, the conductor finger lines contact the underlying emitter layer which reduces solar cell series resistance (R_{S}) and subsequently improves solar cell fill factor percent (FF %) and efficiency percent (Eff %). The non-contacting, floating busbar lines are an electrical connection between the conductor finger lines and outside circuit without making electrical contact to the emitter layer under the busbar lines. By not contacting the underlaying emitter layer, metal induced recombination current density (J₀ₘ) under the metallization lines in the area under the busbar line electrodes is reduced which, subsequently, improves solar cell open circuit voltage (V_{OC}) and Eff %. Metal induced recombination may be a significant loss mechanism in industrial solar cells. One advantage of a dual-print process and non-contacting busbars is an increase in solar cell V_{OC} from a reduction in the J₀ₘ, parameter under the busbar metallization lines. Additional advantages are a reduction in silver metal consumption from narrower conductor line widths and reduced busbar silver content in the busbar lines, and higher solder ribbon adhesion by tailoring the busbar paste composition specifically for adhesion since the requirement for emitter electrical contact is not necessary.

In a single-print process, since one paste is used to print both the conductor metallization finger lines and busbar metallization lines in a single print sequence, the final metallization lines contact the emitter layer in both the area under the conductor finger lines and area under the busbar lines. The disadvantage of the single-print process is a reduction in solar cell V_{OC} from an increase in the J₀ₘ, parameter from contact to the emitter layer under the busbar metallization lines.

The solar cell industry has an efficiency performance metric that defines solar cell efficiency improvement as about 0.03 percent increase in cell or module absolute efficiency. A new metallization paste, or pastes for the case of a dual-print process, that delivers an increase in solar cell absolute efficiency of about 0.03 percent or greater than baseline efficiency will be implemented by solar cell manufactures. Such incremental efficiency increases are essential for the solar cell industry to continue increasing cell and module efficiency.

A thick-film, screen-printable metallization paste for solar cell applications may consist of an organic medium or vehicle, metallic particles, inorganic frit, and additives. For the case of front-side solar cell metallization lines, the paste, or pastes for the case of a dual print process, is screen-printed onto the front-side of a silicon wafer, dried at moderate temperature, and then rapidly fired at relatively high temperature (˜800° C.) in an infrared belt furnace. During the high temperature firing step, the inorganic frit forms a highly wetting liquid phase flux. The liquid phase helps sinter and densify the metal particles and, in the case of conductor line metallization pastes, etches through an electrically insulating SiNₓ:H antireflective coating (ARC) to allow the metallic conductor, e.g., silver, to make electrical contact with the underlying silicon emitter. In the case of floating, non-contacting busbar line metallization pastes, SiNₓ:H removal and subsequent electrical contact to the emitter layer under the busbar metallization lines is not necessary since the goal of the floating busbar is to not contact the underlaying emitter layer.

Interfacial films form between the bulk silver conductor and silicon emitter during the firing process from dissolution of the SiNₓ:H layer and migration of the liquid phase flux and SiNₓ:H reaction products to the interface region. Electrical contact in the case of screen-printed metallization lines is thought to occur by an electron tunneling process through the interfacial films. The extent of SiNₓ H etch-through and subsequent electrical contact is determined by the chemistry of the starting inorganic frit. The frit also acts to adhere the metallization lines to the silicon wafer.

Early generation solar cell screen-printable metallization pastes contained inorganic frits based on lead-silicate (Pb—Si—O) chemistries. More current generation pastes contain tellurite (Te—O) and lead-tellurite (Pb—Te—O) based frits.

Early generation metallization pastes based on lead-silicate frits chemistries required p-type silicon wafers with highly doped n-type emitters (HDE), which have a surface concentration (ND)=˜8×10²⁰ cm⁻³ and sheet resistivities <80 ohm/sq., for the final conductor metallization finger lines to have sufficiently low contact resistivity.

The introduction metallization pastes based on lead-tellurite frit chemistries was a step-change improvement in contact resistivity that allowed the solar cell industry to utilize lightly doped emitters (LDE), which have N_{D}=˜1−2×10²⁰ cm⁻³ or lower and sheet resistivities>90 ohm/sq., and which have much lower recombination velocities and lower saturation currents, and subsequently higher solar cell efficiencies. Low contact resistivity metallizations on LDE wafers have more recently allowed the industry to commercialize further advanced solar cell architectures such as PERC solar cells.

In order for a front-surface conductor metallization to achieve low contact resistivity, the ARC under the conductor line must be removed (dissolved/etched) during the firing process. The ARC is usually a plasma-enhanced chemical vapor deposition (PECVD) SiNₓ:H layer that is typically ˜70 nm thick. This is because the ARC is an insulating layer that prevents current transport from the emitter to the bulk silver conductor during solar cell operation.

During the firing process, the frit in the metallization paste forms a low viscosity liquid-phase flux which migrates by capillary action to the silver-silicon interface (IF) region where it enables the oxidation, dissolution and removal of the SiNₓ:H ARC layer. The primary chemical reaction for the dissolution process during firing is the following redox reaction:

Si₃N₍₄₋ₓ₎H_{x(solid)}+3O_{2(IF liquid flux)}=3SiO_{2(IF liquid)}+(2−0.5x)N_{2(gas)}+(0.5x)H_{2(gas)}

Industrial solar cells are fired under oxidizing conditions. Oxygen in the IF liquid phase flux can be either physical dissolved oxygen in the liquid in the form of gaseous air or chemically dissolved oxygen in the form of metal-oxygen redox couples. During the firing process, the SiO₂ reaction product dissolves into the interfacial liquid phase to expose a fresh surface of SiNₓ:H for subsequent oxidation and dissolution. Hydrogen and nitrogen are gaseous reaction products. The ARC dissolution process continues until the ARC is removed from the interface, exposing the silicon emitter layer. The ΔG (Gibbs free energy of reaction) for the above reaction is −426 kcal, which is a high reaction driving force. Silver that dissolves into the liquid phase flux during firing, and other metals, such as lead, that may be in the starting frit can also act to help drive the ARC dissolution process as shown below.

Si₃N₍₄₋ₓ₎H_{x(solid)}+6Ag₂O_{(liquid flux)}=3SiO_{2(liquid)}+12Ag_{(solid)}+(2−0.5x)N_{2(gas)}+(0.5x)H_{2(gas)}

Si₃N₍₄₋ₓ₎H_{x(solid)}+6PbO_{(liquid flux)}=3SiO_{2(liquid)}+6Pb_{(solid)}+(2−0.5x)N_{2(gas)}+(0.5x)H_{2(gas)}

Both reactions are thermodynamically quite favorable, with ΔGs of −477 kcal and −263 kcal, respectively, which again are high driving forces.

The final interfacial films are composite layers containing reaction products from dissolution of the SiNₓ:H layer and migration of the liquid-phase flux materials to the interface region during the firing process. The extent of SiNₓ:H etch-through and subsequent quality of the resulting electrical contact between the semiconductor and metal conductor is determined by the starting chemistry of the inorganic frit.

The frit chemistry may be designed to take full advantage of the theoretical performance of the solar cell. In the case of a conductor line metallization paste, the frit may etch-through the ARC to maximize contact between the metal and underlying semiconductor Contact to the underlying emitter layer typically results in an increase in recombination losses between the metal and semiconductor (increase in J₀ₘ) and a subsequent reduction in both open circuit voltage (V_{OC}) and short circuit current (I_{SC}).

In the case of a non-contacting, floating busbar metallization paste, ARC etch-through and removal is not necessary. ARC etch-through is eliminated thus reducing the potential for an increase in J₀ₘ, under the busbar lines. A reduction of J₀ₘ, under the busbar lines results in a subsequent increase in solar cell V_{OC} since the area under the busbar metallization lines is not subject to recombination losses. The objective of a floating busbar pastes is to minimize SiNₓ:H removal and accompanying J₀ₘ, losses under the busbar lines.

To achieve additional solar cell efficiency improvements, a dual-print process which includes a non-contacting, floating busbar paste that contains a frit or frits with a chemistry that minimizes SiNₓ:H etch-through and removal under the busbar metallization lines may be developed to further extract the theoretical performance of the solar cell. Prior art does not describe paste chemistries for non-contacting, floating busbar pastes.

In the area of screen-print metallization pastes for crystalline silicon solar cells, prior art describes pastes containing inorganic frit systems where the objective is to remove the SiNₓ:H ARC layer, contact the underlaying emitter layer and, subsequently, reduce contact resistance. Pastes comprising frit systems based on lead-silicate chemistries, where pastes contain a single discrete frit, such as described in U.S. Pat. No. 8,187,505 are known.

Other pastes were subsequently developed comprising frits systems based on lead-tellurium chemistries, such as described in U.S. Pat. No. 8,497,420.

Lead-free tellurium based frits were developed to meet future crystalline solar cell Restriction of Hazardous Substances (RoHS) directives, such as described in U.S. Pat. No. 8,383,001 B2. Current crystalline silicon solar cells RoHS directives do not restrict the use of lead in metallization pastes.

Prior art two frit metallization pastes describe pastes where one frit contains lead chemistries and is tellurium-free and one frit contains tellurium chemistries and is lead-free. U.S. Pat. No. 9,029,692 describes two frit pastes where one frit is a tellurium containing composition that is substantially lead-free, and the other frit is a lead containing composition that is substantially tellurium-free. U.S. Pat. No. 9,029,692 discusses in the specifications that substantially lead-free is a frit containing less than about 10 weight percent lead oxide and substantially tellurium-free is a frit containing less than about 10 weight percent tellurium oxide. U.S. patent application Ser. No. 14/224,917 describes two frit pastes where one frit is lead free and the other frit comprises lead and tellurium with a composition which comprises 10 to 45 weight percent lead oxide, from 54 to 89 weight percent tellurium oxide and 1 to 10 weight percent zinc oxide.

U.S. Pat. No. 10,040,717 describes metallization pastes with multiple discrete inorganic frits comprising tellurium and lead. Again, the goal of these pastes is to remove the SiNₓ:H layer and contact the underlying emitter layer.

### SUMMARY OF THE INVENTION

In one aspect, an electro-conductive, non-contracting thick-film, screen-printable paste includes an inorganic frit system including an inorganic frit including bismuth (Bi) and boron (B) cations wherein 0.01≤Bi≤0.95 wherein Bi is the mole fraction of bismuth cations based on the total number of moles of bismuth and boron cations in the frit. The paste may include a conductive metal powder. The bismuth may be a bismuth oxide and the boron may be a boron oxide.

The paste may include an inorganic frit including bismuth (Bi) and boron (B) cations wherein 0.01≤Bi≤0.85 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.75 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.65 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.55 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.45 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.35 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.25 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.15 wherein Bi is the mole fraction of bismuth cations based on the total number of moles of bismuth and boron cations in the frit.

The paste may include an inorganic frit including bismuth (Bi) and boron (B) cations wherein 0.01≤Bi≤0.05 wherein Bi is the mole fraction of bismuth cations based on the total number of moles of bismuth and boron cations in the frit.

The inorganic frit may comprise a bismuth-born-metal-oxygen composition of

$$[ {{Bi}_{x} ( {B}_{y} {M}_{z} {{M}_{{z}^{′}}^{′} ( {M}_{{z}^{i}}^{i} )}_{( 1 - x )} ]}^{{n}^{+}} {O}_{\frac{{n}^{+}}{2}} , \qquad$$

wherein 0<z≤0.7 and z is the mole fraction of metal (M) cations based on the total number of moles of bismuth, boron and metal cations, respectively, selected from one of Li, Na, K, Rb, Cs, Mg, Ca, Sr, Ba, Al, Si, P, Sc, Ti, V, Cr, Mn, Fe, Co, Ni, Cu, Zn, Ga, Ge, Y, Zr, Nb, Mo, Ru, Pd, Ag, In, Sn, Sb, Te, Hf, Ta, W, Pt, Au, Tl, Pb, La and the other lanthanide elements and mixtures thereof.

The inorganic frit may comprise metal cations including one of oxides, halides and fluorides.

The inorganic frit system may comprise 0.3 to 10 weight percent of the paste based on a total amount of solids of the paste.

The inorganic frit system may include more than one inorganic frit.

The inorganic frit system may be lead-fee.

The metal powder may include at least a portion of silver.

The silver powder content may comprise 75 to 99.5 weight percent based on a total amount of solids in the paste.

In another aspect, the floating, non-contacting electro-conductive thick-film, screen-printable paste includes an organic medium comprising one of an organic vehicle and additives is described.

In another aspect a dual-print process comprising a floating, non-contacting electro-conductive thick-film, screen-printable paste is described.

In another aspect, a photovoltaic cell comprising a floating, non-contacting electro-conductive thick-film, screen-printable paste is described.

In another aspect, a photovoltaic cell comprising a floating, non-contacting electro-conductive thick-film, screen-printable paste wherein the paste is used to print busbar electrodes.

In another aspect, a photovoltaic cell with a lightly doped emitter layer and high sheet resistance comprising a floating, non-contacting electro-conductive thick-film, screen-printable paste is described.

In another aspect, a photovoltaic cell with passivated emitter rear (PERC cell) comprising a floating, non-contacting electro-conductive thick-film, screen-printable paste is described.

In another aspect, a photovoltaic PERC cell with selective emitter (PERC-SE cell) comprising a floating, non-contacting electro-conductive thick-film, screen-printable paste is described.

In another aspect, the floating, non-contacting electro-conductive thick-film, screen-printable paste does not contact the emitter layer of the photovoltaic cell is described.

In another aspect, an article comprising a photovoltaic module having been formed using the photovoltaic cell comprising a floating, non-contacting electro-conductive thick-film, screen-printable paste is described.

### BRIEF DESCRIPTION OF THE DRAWINGS

The advantages of the invention and preferred embodiments are more fully understood by referencing the following detailed descriptions of the drawings.

FIG. 1 is a cross section diagram of a front-contact, p-type crystalline silicon PV solar cell with floating, non-contact busbar electrodes.

FIG. 2 is a process flow diagram for industrial manufacturing of a dual printed, p-type crystalline silicon PV solar cell with floating, non-contacting busbar electrodes.

FIG. 3 is a process flow diagram for industrial manufacturing of crystalline silicon PV solar cell module comprising a module having been formed using crystalline silicon PV solar cells with floating, non-contacting busbars.

FIG. 4 is a process flow diagram for industrial manufacturing of a screen-printable busbar paste.

### DETAILED DESCRIPTION

Each of the additional features and teachings disclosed below can be utilized separately or in conjunction with other features and teachings to provide a device, system, and/or method for thick-film, screen-printable, floating, non-contact busbar paste. In one embodiment, the paste may be applied to crystalline silicon solar cell emitter surfaces. Representative examples of the present invention, which examples utilize many of these additional features and teachings both separately and in combination, will now be described in further detail with reference to the attached drawings. This detailed description is merely intended to teach a person of skill in the art further details for practicing preferred aspects of the present teachings and is not intended to limit the scope of the invention. Therefore, combinations of features and steps disclosed in the following detail description may not be necessary to practice the invention in the broadest sense and are instead taught merely to particularly describe representative examples of the present teachings.

Moreover, the various features of the representative examples and the dependent claims may be combined in ways that are not specifically and explicitly enumerated in order to provide additional useful embodiments of the present teachings. In addition, it is expressly noted that all features disclosed in the description and/or the claims are intended to be disclosed separately and independently from each other for the purpose of original disclosure, as well as for the purpose of restricting the claimed subject matter independent of the compositions of the features in the embodiments and/or the claims. It is also expressly noted that all value ranges or indications of groups of entities disclose every possible intermediate value or intermediate entity for the purpose of original disclosure, as well as for the purpose of restricting the claimed subject matter.

Devices, methods, and systems are described for thick-film, screen-printable, floating, non-contact busbar paste. In one embodiment, the non-contacting busbar paste may be applied to crystalline silicon solar cell emitter surfaces. In one embodiment the non-contacting busbar paste may be used in a dual-print process for screen-printing busbar electrodes. In one embodiment the frit in the busbar paste contains both bismuth and boron. In one embodiment, the described non-contacting busbar paste has superior solar cell performance compared to single-print electroconductive pastes. Examples of the non-contacting busbar paste are shown in the following examples. The examples show a solar cell performance improvement metric that is measured in hundreds of a percent absolute efficiency.

The electroconductive thick-film, screen-printable paste compositions are useful for printing front-side busbar electrodes on crystalline silicon solar cell emitter surfaces, and the like. Other applications may include screen-printable paste compositions for printing electrodes for hybrid circuits applications, and the like.

In one embodiment, an electro-conductive thick-film, screen-printable paste for printing non-contacting electrodes on crystalline silicon solar cell emitter surfaces is disclosed. The thick-film paste may include: an inorganic frit or fits, an electrically conductive metal powder, and an organic medium. The electrically conductive metal powder may include a metal, such as silver or silver in combination with other conductive metals, such a nickel and copper. The frit and metal powder may be dispersed in an organic medium to form a thick-film, screen-printable paste.

The non-contacting inorganic frit system addresses the need to reduce the J₀ₘ, parameter under the busbar electrodes in dual-print busbar metallization pastes to maximize the global performance of the solar cell. The ability to reduce the J₀ₘ, parameter under the busbar electrodes is especially important for pastes designed for advanced solar cell architectures such as Passivated Emitter Rear Contact (PERC), Passivated Emitter Rear Locally Diffused (PERL), Passivated Emitter Rear Totally Diffused (PERT), etc. where final solar cell efficiency is much more dependent on extracting the theoretical performance of the cell. The disclosed non-contacting busbar paste compositions may be used to manufacturer screen-printed, crystalline silicon solar cells with improved performance.

In one embodiment, a method for manufacturing or producing a PV cell is also disclosed and includes a crystalline silicon PV cell having been formed using the non-contacting electro-conductive thick-film, screen-printable busbar paste. In another embodiment, the PV cell having been formed using the non-contacting electro-conductive thick-film, screen-printable bus paste has an emitter surface that is lightly doped with high sheet resistance and passivated with an oxide layer such as alumina or silica.

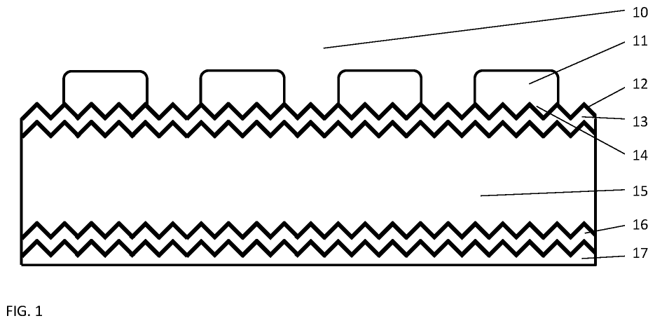

FIG. 1 is a cross section diagram of a front-contact, p-type crystalline silicon PV solar cell with floating, non-contact busbar electrodes (lines) showing details of the solar cell 10 in an embodiment. The cell 10 may include front-side silver busbar electrodes 11, an antireflective coating (SiNₓ:H) 12, a phosphorus doped n⁺ emitter 13, a non-contacting interface between the busbar and emitter surface 14, a p-type crystalline silicon wafer 15, a p⁺ back surface field 16, and a back-side aluminum metallization 17. In one embodiment the front-side silver busbar lines are floating and not in contact with the underlaying emitter surface.

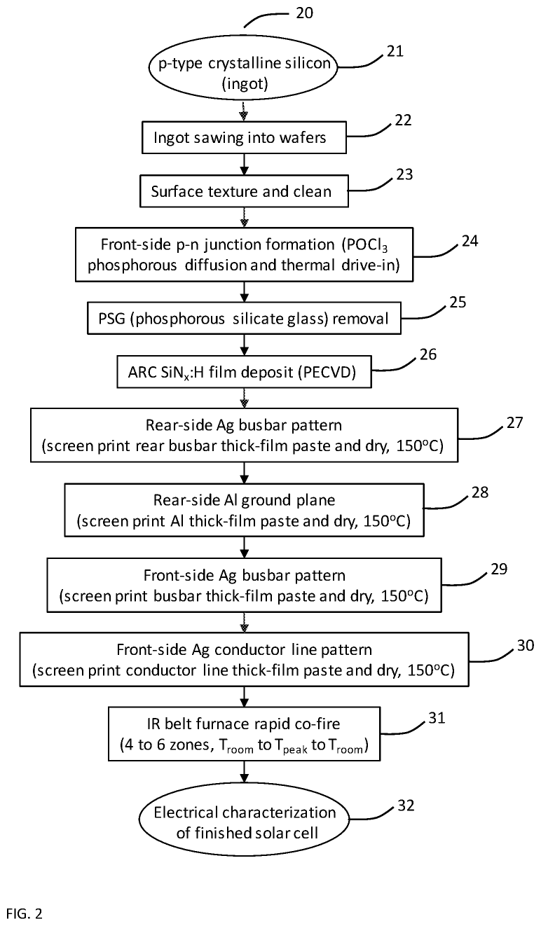

FIG. 2 is a process flow diagram 20 for industrial manufacturing process of a typical dual printed, p-type crystalline silicon PV solar cell with floating, non-contacting busbar electrodes (lines). In step 21, a p-type crystalline silicon ingot may be provided. In step 22, the ingot may be sawed into wafers. In step 23, the wafer surface may be textured and cleaned. In step 24, a front-side junction may be formed by PECVD phosphorus (POCl₃) diffusion and thermal drive-in. In step 25, phosphorus silicate glass (PSG) may be removed. In step 26, the front-surface SiNₓ:H ARC by PECVD may be deposited. In step 27, the rear-surface silver busbar may be screen-printed on the rear surface using rear-side silver busbar paste. In step 28, the rear-surface aluminum ground plane may be screen-printed on the rear surface using rear-side aluminum paste. In step 29, the front-surface silver busbar pattern may be screen-printed using non-contacting silver busbar paste. In step 30, the front-surface silver conductor line grid pattern may be screen-printed using contacting silver conductor line paste and dried. In step 31, the screen-printed wafer may be rapidly co-fired in an IR belt furnace. In step 32, an electrically characterized finished solar cell is provided. In one embodiment, the solar cell manufacturing process is the screen-printed, non-contacting busbar electrode pattern on the front surface of the solar cell. In one embodiment, a crystalline Si solar cell may be formed using the disclosed electro-conductive, non-contacting, thick-film, screen-printable busbar paste.

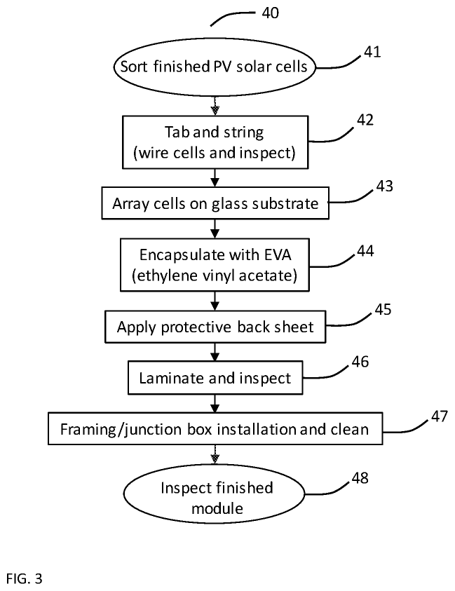

In another embodiment, a process for producing a PV module comprising a module having been formed using crystalline silicon PV solar cells with floating, non-contacting busbars is described. FIG. 3 is a process flow diagram 40 for industrial manufacturing of crystalline silicon PV solar cell module comprising a module having been formed using crystalline silicon PV solar cells with floating, non-contacting busbars. In step 41, finished crystalline silicon solar cells may be sorted. In step 42, the solar cells may be tabbed, strung and inspected. In step 43, an array of solar cells on a glass substrate may be provided. In step 44, the solar cell array may be encapsulation with ethylene-vinyl acetate (EVA). In step 45, a protective back-sheet may be applied. In step 46, the solar cell array may be laminated and inspected. In step 47, the module may be framed, cleaned and junction box may be installed. In step 48, the finished module may be inspected. In one embodiment, a solar cell module may be formed using crystalline silicon solar cells having been formed using the disclosed electro-conductive thick-film, screen-printable non-contacting busbar paste.

a) The Inorganic Frit System

In one embodiment, an inorganic frit for use, for example, in an electro-conductive thick-film, screen-printable paste for printing front-side non-contacting busbar lines on crystalline silicon solar cell emitter surfaces is described. The inorganic frit system comprises a frit or frits containing bismuth and boron dispersed in the paste.

The inorganic frit during the high-temperature firing step forms a liquid phase flux that etches the electrically insulating SiNₓ:H antireflective coating (ARC) of the solar cell. For a non-contacting, floating busbar paste, ARC etch-through and removal is not necessary. ARC etch-through should be minimized thus eliminating the potential for an increase in J₀ₘ, under the busbar lines. A reduction in J₀ₘ, under the busbar lines results in an increase in solar cell V_{OC} since the area under the busbar is not subjected to recombination losses.

The non-contacting frit when used in a thick-film, screen-printable paste to print front-side solar cell busbar electrodes (e.g., silver) improves overall solar cell performance by approximately a tenth of a percent absolute efficiency or more.

The non-contacting frit also acts as an adhesion medium to adhere the metallization lines to the underlying semiconductor substrate, thereby ensuring the lifetime reliability of the solar cell device.

The non-contacting frit may comprise a frit with amorphous, crystalline, or partially crystalline phases. It may comprise frits with various compounds including, but is not limited to, oxides, fluorides, chlorides or salts, alloys, and elemental materials.

In an embodiment, the non-contacting frit may comprise an inorganic frit containing bismuth and boron. The bismuth may be bismuth oxide and the boron may be boron oxide. In another embodiment, the non-contacting frit comprises a frit with amorphous, crystalline, or partially crystalline phases and mixtures thereof.

In an embodiment the inorganic frit may comprise a bismuth-born-metal-oxygen composition of Formula 1,

$$[ {{Bi}_{x} ( {B}_{y} {M}_{z} {{M}_{{z}^{′}}^{′} ( {M}_{{z}^{i}}^{i} )}_{( 1 - x )} ]}^{{n}^{+}} {O}_{\frac{{n}^{+}}{2}} \qquad$$

Wherein x is the mole fraction of bismuth (B), y is the mole fraction of boron (B), z is the mole fraction of metal cations (M) and n⁺ is the valance number of the bismuth, boron and metal cations. In an embodiment, 0<z≤0.7 and z is the mole fraction of metal cations based on the total number of moles of bismuth, boron and metal cations. The metal cations may be selected from one of Li, Na, K, Rb, Cs, Mg, Ca, Sr, Ba, Al, Si, P, Sc, Ti, V, Cr, Mn, Fe, Co, Ni, Cu, Zn, Ga, Ge, Y, Zr, Nb, Mo, Ru, Pd, Ag, In, Sn, Sb, Te, Hf, Ta, W, Pt, Au, Tl, Pb, La and the other lanthanide elements and mixtures thereof. In another embodiment, the metal cations comprise oxides, halides or fluorides.

In another embodiment, the inorganic frit comprises a composition of Formula 1 wherein 0.01≤Bi≤0.95 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In one example, a paste with a frit wherein Bi=0.95 (where Bi is the fraction amount of bismuth based on the total amount of bismuth and boron) and z=0.7 has a chemical formula according to Formula 1 of (Bi_{(0.285)}B_{(0.015)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.85 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.85 (where Bi is the fraction amount of bismuth based on the total amount of bismuth and boron) and z=0.7 has a chemical formula according to Formula 1 of (Bi_{(0.255)}B_{(0.045)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.75 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.75 (where Bi is the fraction amount of bismuth based on the total amount of bismuth and boron) and z=0.7 has a chemical formula according to Formula 1 of (Bi_{(0.225)}B_{(0.075)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.65 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.65 (where Bi is the fraction amount of bismuth based on the total amount of bismuth and boron) and z=0.7 has a chemical formula according to Formula 1 of (Bi_{(0.195)}B_{(0.105)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.55 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.55 (where Bi is the fraction amount of bismuth based on the total amount of bismuth and boron) and z=0.7 has a chemical formula according for formula 1 of (Bi_{(0.165)}B_{(0.135)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.45 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.45 (where Bi is the fraction amount of bismuth based on the total amount of bismuth and boron) and z=0.7 has a chemical formula according to Formula 1 of (Bi_{(0.135)}B_{(0.165)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.35 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization lines to the SiNₓ:H layer and underlaying emitter layer.

In another example, a paste with a frit wherein Bi=0.35 (where Bi is the fraction amount of bismuth based on the total amount of bismuth and boron) and z=0.7 has a chemical formula according to Formula 1 of (Bi_{(0.105}B_{(0.195)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.25 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization layer to the SiNₓ:H layer and underlaying emitter layer.

In another example, a paste with a frit wherein Bi=0.25 (where Bi is the fraction amount of bismuth based on the total amount of bismuth and boron) and z=0.7 has a chemical formula according to Formula 1 of (Bi_{(0.075)}B_{(0.225)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.15 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization layer to the SiNₓ:H layer and underlaying emitter layer.

In another example, a paste with a frit wherein Bi=0.15 (where Bi is the fraction amount of bismuth based on the total amount of bismuth and boron) and z=0.7 has a chemical formula according to Formula 1 of (Bi_{(0.045)}B_{(0.225)}M_{(0.7)})ⁿ⁺O_{n/2}. During the solar cell firing process, the frit in the metallization paste forms a liquid phase flux that has a chemistry determined by the starting chemistry of the frit.

In another embodiment, the inorganic frit comprises a composition of Formula 1 wherein 0.01≤Bi≤0.05 in which Bi is the mole fraction of bismuth cation based on the total number of bismuth and boron cations in the frit. In an embodiment, the frit is dispersed into the paste. In an embodiment, the paste is printed onto the front-side of the solar cell wafer. In an embodiment the paste is printed as busbar electrodes. In an embodiment, during the firing process the frit forms a liquid phase flux that migrates to the interface region between the insulating SiNₓ:H antireflective coating layer and bulk metallization layer without etching through the SiNₓ:H layer and contacting the underlaying emitter layer. In an embodiment, the interfacial liquid phase adheres the metallization layer to the SiNₓ:H layer and underlaying emitter layer.

In another example, a paste with a frit wherein Bi=0.05 (where Bi is the fraction amount of bismuth based on the total amount of bismuth and boron) and z=0.7 has a chemical formula according to Formula 1 of (Bi_{(0.015)}B_{(0.285)}M_{(0.7)})ⁿ⁺O_{n/2}. During the solar cell firing process, the frit in the metallization paste forms a liquid phase flux that has a chemistry determined by the starting chemistry of the frit.

In another embodiment, the frit comprises a composition of Formula 1, wherein the frit may be formulated with bismuth and boron amounts as shown in Table 1. That is, a frit with 0.1≤Bi≤0.95 has a Bi:B mole ratio=95:05 and a Bi₂O₃:B₂O₃ weight ratio=99.22:0.78, a frit with a 0.1≤Bi≤0.9 has a Bi:B mole ratio=90:10 and a Bi₂O₃:B₂O₃ weight ratio=98.37:1.63, a frit with a 0.1≤Bi≤0.85 has a Bi:B mole ratio=85:15 and a Bi₂O₃:B₂O₃ weight ratio=97.43:2.57, and a frit with 0.1≤Bi≤0.8 has a Bi:B mole ratio=80:20 and a Bi₂O₃:B₂O₃ weight ratio=96.4:3.6, etc. The individual frit is dispersed into a paste, forming a paste shown in Table 1 comprising a frit with Bi:B ratios based on the total amount of bismuth and boron in the frit.

TABLE 1
Frits comprising bismuth and boron compositions of Formula 1.

| | | Bi:B | Bi₂O₃:B₂O₃ |
|---|---|---|---|
| Paste | Frit | Mole Ratio | Weight Ratio |
| 1 | 0.1 ≤ Bi ≤ 95 | 95:05 | 99.22:078 |
| 2 | 0.1 ≤ Bi ≤ 85 | 85:15 | 97.43:2.57 |
| 3 | 0.1 ≤ Bi ≤ 75 | 75:25 | 95.26:4.74 |
| 4 | 0.1 ≤ Bi ≤ 65 | 65:35 | 92.55:7.45 |
| 5 | 0.1 ≤ Bi ≤ 55 | 55:45 | 88.11:10.89 |
| 6 | 0.1 ≤ Bi ≤ 45 | 45:55 | 84.56:15.44 |
| 7 | 0.1 ≤ Bi ≤ 35 | 35:65 | 78.28:21.72 |
| 8 | 0.1 ≤ Bi ≤ 25 | 25:75 | 69.05:30.95 |
| 9 | 0.1 ≤ Bi ≤ 15 | 15:85 | 54.15:45.85 |
| 10 | 0.1 ≤ Bi ≤ 05 | 05:95 | 26.05:73.95 |

In another embodiment, frits including the composition of Formula 1 may be formulated without lead.

The frits can be prepared by any solid-state synthesis process by mixing appropriate quantities of starting ingredients, heating the mixture of starting ingredients in air or an oxygen containing atmosphere to a temperature where the starting ingredients react with one another to form a reaction product and then cooling the reaction product to room temperature to form a solid phase frit. The frit may be amorphous, crystalline or a mixture thereof. The frit is then ground to provide a powder of appropriate particle size for dispersing into a screen-printable paste.

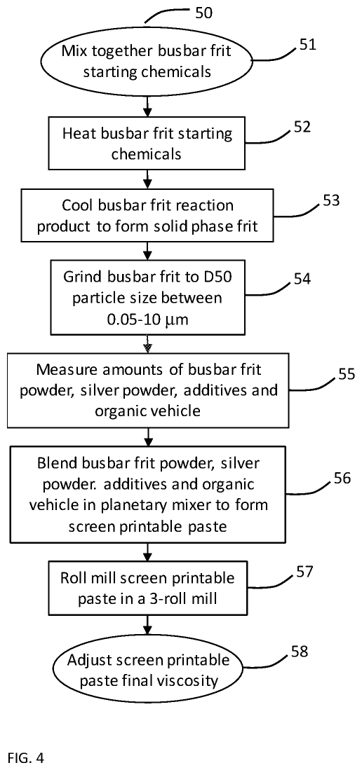

FIG. 4 is a process flow diagram 50 for industrial manufacturing of a screen-printable busbar paste. In step 51, mix together appropriate amounts of busbar frit starting chemical constituents. In step 52, heat (700° C.-1300° C.) busbar frit starting chemical constituents in air or oxygen containing atmosphere to react starting ingredients. In step 53, cool (quench) busbar frit reaction product to room temperate to form solid phase inorganic frit. In step 54, grind (mill) busbar frit inorganic reaction product to a D50 particle size between 0.05-10 μm. In step 55, measure appropriate amounts of busbar frit powder, silver powder, additives and organic vehicle. In step 56, blend together busbar frit powder, silver powder, additives and organic vehicle in planetary mixer to form homogeneous paste with a viscosity between 300-600 Pa-s. In step 57, roll mill paste in a 3-roll mill to a mean FOG of 10 μm. In step 58, adjust paste to a final viscosity to between 200-450 Pa-s.

In one aspect, the starting ingredients are mixed together, heated to around 700° C.-1300° C. for around 0.5 hr.-2 hr. and then rapidly cooled to room temperature forming a frit. The starting ingredients may be oxides, carbonates, halides, sulfates, phosphates or salts or combinations thereof. The frit is then ground by ball milling or jet milling to a D50 particle size of about 0.05 to 10 μm, preferably to about 0.2 to 4 μm.

In an embodiment, the frit comprises 0.3 to 10 weight percent based on the total solids of the screen-printable, thick film paste.

b) The Electrically Conductive Metal Powder

In another aspect, an electrically conductive metal powder for use in an electro-conductive thick-film, screen-printable paste for printing front-side electrodes on crystalline silicon solar cell emitter surfaces is disclosed.

In one embodiment, the electrically conductive metal comprises Ag, Au, Cu, Ni and alloys thereof and combinations thereof. The electrically conductive metal can be in the form of a flake, spherical, granular, powder and mixtures thereof. In one embodiment, the metal comprises silver. Silver can be in the form of silver metal, silver compounds, and mixtures thereof. Appropriate compounds include silver alloys, silver oxide (Ag₂O), and silver salts, such as silver chlorides, nitrates, acetates, and phosphates.

In one embodiment, the silver powder comprises 75 to 99.5 weight percent based on the total solids of the screen-printable, thick film paste.

c) The Organic Medium

In another aspect, an organic medium for use in an electro-conductive thick-film, screen-printable paste for printing front-side electrodes on crystalline silicon solar cell emitter surfaces is disclosed.

In one embodiment, the inorganic components are mixed with an organic medium to form a viscous paste having a rheology suitable for screen-printing. In another embodiment, the organic medium consists of an organic solvent and one or more polymeric binders, a surfactant and a thixotropic agent and combinations thereof.

### Examples

The following examples illustrate the inventions disclosed herein without limitations.

Screen-Printable Busbar Paste Preparation

Screen-printable busbar pastes for Pastes 1-8 were prepared by mixing silver powder (90 wt %), inorganic frit (2 wt %) and organic components (8 wt %) in an industrial planetary mixer followed by roll milling and viscosity adjustment. Planetary mixing consisted of blending paste components until homogeneous with a viscosity between 200 and 600 Pa-s. The paste was then roll milled in a 3-roll mill to a mean fineness of grind (FOG) of approximately 5 μm in accordance with ASTM Standard Test Method D 1210-05. After 24 hours, the paste was adjusted to a final viscosity between 200 and 450 Pa-s.

d) Solar Cell Preparation

Busbar paste solar cell performance for solar cell Examples 1-12 was evaluated on commercially available industrially processed, POCl₃ diffused n+−p−p+Si wafers with a front surface phosphorous emitter diffusion profile typically used by industry. Wafers were p-type, front junction, mono-crystalline Si pseudo-square (156 mm×156 mm, 180 μm thick) with a bulk resistivity of ˜2 Ω-cm and alkaline etched, phosphorous diffused at front surface. The wafers had a 75 nm thick front-side (FS) PECVD SiNₓ:H antireflective coating (ARC).

An industrial Baccini screen-printer was used to screen-print solar cell Examples 1-12 front surface silver conductor lines and busbar lines. Solar cell Examples 1-12 were prepared by a dual print process which consisted of printing the busbar pattern and conductor line patterns in two separate print sequences using two separate print screens. In the first print sequence, the busbar line pattern was printed using a 360 mesh screen with 0.7 mm openings, i.e., 0.7 mm busbar. In the second print sequence, the conductor line pattern was printed using a 400 mesh screen with 28 μm openings. The FS print pattern had four busbars and 103 conductor lines. The fired FS conductor line mean width was ˜35-40 μm and mean line height was ˜15 μm. The fired FS busbar line mean width was 720 μm and mean height was 4 μm. A dual-print process was used to print all of the solar cells to allow for an unbiased comparison between busbar pastes and conductor line paste. The back side consisted of a full ground plane aluminum conductor with continuous silver tabbing bus bars. An industrial Despatch furnace was used to fire the screen-printed solar cell wafers. An industrial Berger I-V tester was used to measure solar cell electrical parameters. Solar cell efficiency (Eff), fill factor (FF), open circuit voltage (Voc), short circuit current (Isc) and series resistance (Rs) are shown in Table 6. The electrical data values are median values for about 10 solar cells.

Non-Contacting Busbar Pastes

Six exemplary electro-conductive thick-film pastes (Pastes 1-6) were prepared as non-contacting busbar pastes.

Non-contacting Pastes 1-6 were prepared with non-contacting Frits 1-6, respectively with bismuth-boron-metal-oxygen compositions according to

$$[ {{Bi}_{x} ( {B}_{y} {M}_{z} {{M}_{{z}^{′}}^{′} ( {M}_{{z}^{i}}^{i} )}_{( 1 - x )} ]}^{{n}^{+}} {O}_{\frac{{n}^{+}}{2}} \qquad$$

as shown in TABLE 2.

Non-contacting Paste 1 contained Frit 1 with x=0.80 where x is the fractional amount of bismuth cation (Bi) based on the total amount of bismuth and boron (B) cations, and z=0.054 where z is the fractional amount of metal cations (M) based on the total amount of bismuth, boron, and metal cations. Frit 1 had metal cations (M) selected from Al, Bi, B, Ca, Li, Mg, Na, Si, Ti, W and Zn.

Non-contacting Paste 2 contained Frit 2 with x=0.80 where x is the fractional amount of bismuth cation (Bi) based on the total amount of bismuth and boron (B) cations, and z=0.031 where z is the fractional amount of metal cations (M) based on the total amount of bismuth, boron, and metal cations. Frit 2 had metal cations (M) selected from Al, Bi, B, Ca, Li, Mg, Na, Si, Ti, W and Zn.

Non-contacting Paste 3 contained Frit 3 with x=0.90 where x is the fractional amount of bismuth cation (Bi) based on the total amount of bismuth and boron (B) cations, and z=0.031 where z is the fractional amount of metal cations (M) based on the total amount of bismuth, boron, and metal cations. Frit 3 had metal cations (M) selected from Al, Bi, B, Ca, Li, Mg, Na, Si, Ti, W and Zn.

Non-contacting Paste 4 contained Frit 4 with x=0.65 where x is the fractional amount of bismuth cation (Bi) based on the total amount of bismuth and boron (B) cations, and z=0.031 where z is the fractional amount of metal cations (M) based on the total amount of bismuth, boron, and metal cations. Frit 4 had metal cations (M) selected from Al, Bi, B, Ca, Li, Mg, Na, Si, Ti, W and Zn.

Non-contacting Paste 5 contained Frit 5 with x=0.57 where x is the fractional amount of bismuth cation (Bi) based on the total amount of bismuth and boron (B) cations, and z=0.031 where z is the fractional amount of metal cations (M) based on the total amount of bismuth, boron, and metal cations. Frit 5 had metal cations (M) selected from Al, Bi, B, Ca, Li, Mg, Na, Si, Ti, W and Zn.

Non-contacting Paste 6 contained Frit 6 with x=0.85 where x is the fractional amount of bismuth cation (Bi) based on the total amount of bismuth and boron (B) cations, and z=0.031 where z is the fractional amount of metal cations (M) based on the total amount of bismuth, boron, and metal cations. Frit 6 had metal cations (M) selected from Al, Bi, B, Ca, Li, Mg, Na, Si, Ti, W and Zn.

Conductor Line Pastes

Two exemplary electro-conductive thick-film pastes (Pastes 7 and 8) were prepared as conductor line pastes. Pastes 7 and 8 are industry typical Te—Pb conductor line pastes designed to contact the solar cell emitter layer.

Solar Cell Electrical Data

TABLE 3 shows electrical data for Examples 1-6 for solar cells prepared by dual-print screen-printing. Column 2 shows the pastes used to print the busbar line electrodes. Column 3 shows the pastes used to print the conductor line electrodes. In Examples 1-6 the busbar line electrodes were printed with non-contacting Pastes 1-6. In Examples 1-6 the conductor line electrodes were also printed with non-contacting Pastes 1-6. The TABLE 3 electrical data show that solar cell examples fabricated from non-contacting pastes, containing non-contacting frits, have poor R_{S}, FF and Eff solar cell electrical data which indicates minimal electrical contact to the solar cell emitter layer under both the conductor lines and busbar lines.

TABLE 4 shows electrical data for Examples 7-9 for solar cells prepared by dual-print screen-printing. Column 2 shows the pastes used to print the busbar line electrodes. Column 3 shows the pastes used to print the conductor line electrodes. In Example 7 the busbar line electrodes were printed with non-contact Paste 1. In Example 7 the conductor line electrodes were printed with contacting Paste 7. In Examples 8 the busbar line electrodes were printed with non-contacting Paste 2. In Examples 8 the conductor line electrodes were printed with contacting Paste 7. In Example 9 the busbar line electrodes were printed with contacting Paste 7. In examples 9 the conductor line electrodes were also printed with contacting Paste 7. TABLE 4 allows for a comparison of solar cells with busbar line electrodes printed with non-contacting pastes (non-contacting Pastes 1 and 2 in Examples 7 and 8) to solar cells with busbar line electrodes printed with contacting paste (contacting Paste 7 in Example 9). The TABLE 4 electrical data show that solar cell examples printed with non-contacting busbar line electrodes (Example 7 and 8) have superior V_{OC} and subsequently superior Eff % compared with Example 9 which had contacting busbar line electrodes (contacting Paste 7). The increase in V_{OC} and Eff % in Examples 7 and 8, compared to Example 9, is from a reduction in recombination in the region under the non-contacting busbar line electrodes from the non-contacting busbar pastes.

TABLE 5 shows electrical data for Examples 10 and 11 for solar cells prepared by dual-print screen-printing. Column 2 shows pastes used to print the busbar line electrodes. Column 3 shows pastes used to print the conductor line electrodes. In Example 10 the busbar line electrodes were printed with non-contacting Paste 6. In Example 10 the conductor line electrodes were printed with contacting Paste 8. In Example 11 the busbar line electrodes were printed with contacting Paste 8. In example 11 the conductor line electrodes were also printed with contacting Paste 8. TABLE 5 allows for a comparison of solar cells with busbar line electrodes printed with non-contacting pastes (non-contacting Paste 6 in Example 10) to solar cells with busbar line electrodes printed with contacting paste (Paste 8 in Example 11). The TABLE 5 electrical data show that solar cell examples printed with non-contacting busbar line electrodes (Example 10) have superior V_{OC} and subsequently superior Eff % compared with Example 11 which had contacting busbar line electrodes (Paste 8). The increase in V_{OC} and Eff % in Examples 10, compared to Example 11, is from a reduction in recombination in the region under the non-contacting busbar electrodes from the non-contacting busbar pastes.

TABLE 2
Compositions of Frits 1-6

| ${[ {{Bi}_{x} ( {B}_{y} {M}_{z} {M}_{z} {M}_{{z}^{i}}^{i} )}_{( 1 - x )} ]}^{{n}^{+}} {O}_{\frac{{n}^{+}}{?}}$ | Frit 1 | Frit 2 | Frit 3 | Frit 4 | Frit 5 | Frit 6 |
|---|---|---|---|---|---|---|
| x/(x + y) = | 0.80 | 0.80 | 0.90 | 0.65 | 0.57 | 0.85 |
| Bi (cation %) | 75.68 | 77.51 | 87.2 | 62.89 | 55.37 | 82.35 |
| B (cation %) | 18.92 | 19.38 | 9.69 | 34 | 41.52 | 14.54 |
| M (cation %) | 5.40 | 3.11 | 3.11 | 3.11 | 3.11 | 3.11 |

M selected from Al, Bi, B, Ca, Li, Mg, Na, Si, Ti, Wand Zn

TABLE 3
Solar Cell Electrical Data

| | Busbar Line | Conductor Line | | | |
|---|---|---|---|---|---|
| | Electrode | Electrode | Rs (mΩ) | FF (%) | Eff (%) |
| Example 1 | Paste 1 | Paste 1 | 76.9 | 24.80 | 2.22 |
| Example 2 | Paste 2 | Paste 2 | 162.1 | 23.70 | 1.43 |
| Example 3 | Paste 3 | Paste 3 | 81.2 | 24.80 | 1.16 |
| Example 4 | Paste 4 | Paste 4 | 348.4 | 22.70 | 0.57 |
| Example 5 | Paste 5 | Paste 5 | 415.6 | 20.10 | 0.38 |
| Example 6 | Paste 6 | Paste 6 | 64.1 | 25.30 | 1.87 |

TABLE 4
Solar Cell Electrical Data

| | Busbar | Conductor | | | | |
|---|---|---|---|---|---|---|
| | Line | Line | Isc | Voc | FF | Eff |
| | Electrode | Electrode | (mA) | (mV) | (%) | (%) |
| Example 7 | Paste 1 | Paste 7 | 9.14 | 636 | 79.81 | 19.01 |
| Example 8 | Paste 2 | Paste 7 | 9.15 | 637 | 80.33 | 19.22 |
| Example 9 | Paste 7 | Paste 7 | 9.15 | 634 | 79.30 | 18.91 |

TABLE 5
Solar Cell Electrical Data

| | Busbar | Conductor | | | | |
|---|---|---|---|---|---|---|
| | Line | Line | Isc | Voc | FF | Eff |
| | Electrode | Electrode | (mA) | (mV) | (%) | (%) |
| Example 10 | Paste 6 | Paste 8 | 9.17 | 638 | 79.30 | 19.10 |
| Example 11 | Paste 8 | Paste 8 | 9.15 | 634 | 79.32 | 18.90 |

The present invention or any part(s) or function(s) thereof, may be implemented using hardware, software, or a combination thereof, and may be implemented in one or more computer systems or other processing systems. A computer system for performing the operations of the present invention and capable of carrying out the functionality described herein can include one or more processors connected to a communications infrastructure (e.g., a communications bus, a cross-over bar, or a network). Various software embodiments are described in terms of such an exemplary computer system. After reading this description, it will become apparent to a person skilled in the relevant art(s) how to implement the invention using other computer systems and/or architectures.

The foregoing description of the preferred embodiments of the present invention has been presented for purposes of illustration and description. It is not intended to be exhaustive or to limit the invention to the precise form or to exemplary embodiments disclosed. Obviously, many modifications and variations will be apparent to practitioners skilled in this art. Similarly, any process steps described might be interchangeable with other steps in order to achieve the same result. The embodiment was chosen and described in order to best explain the principles of the invention and its best mode practical application, thereby to enable others skilled in the art to understand the invention for various embodiments and with various modifications as are suited to the particular use or implementation contemplated. It is intended that the scope of the invention be defined by the claims appended hereto and their equivalents. Reference to an element in the singular is not intended to mean “one and only one” unless explicitly so stated, but rather means “one or more.” Moreover, no element, component, nor method step in the present disclosure is intended to be dedicated to the public regardless of whether the element, component, or method step is explicitly recited in the following claims. No claim element herein is to be construed under the provisions of 35 U.S.C. Sec. 112, sixth paragraph, unless the element is expressly recited using the phrase “means for . . . .”

Furthermore, the purpose of the foregoing Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the present invention in any way. It is also to be understood that the steps and processes recited in the claims need not be performed in the order presented.

1. An electro-conductive thick-film, screen-printable paste comprising:
a non-contacting inorganic frit system including an inorganic frit including bismuth (Bi) and boron (B) wherein 0.01≤Bi≤0.95 wherein Bi is the mole fraction of bismuth cations based on the total number of moles of bismuth and boron cations in the frit.

2. The paste of claim 1, further comprising a conductive metal powder wherein a portion of the powder is silver.

3. The paste of claim 1, wherein the bismuth is a bismuth oxide and the boron is a boron oxide.

4. The paste of claim 1, wherein the bismuth and boron comprise halides and fluorides.

5. The paste in claim 1 wherein 0.01≤Bi≤0.85.

6. The paste in claim 1, wherein 0.01≤Bi≤0.75.

7. The paste in claim 1, wherein 0.01≤Bi≤0.65.

8. The paste in claim 1, wherein 0.01≤Bi≤0.55.

9. The paste in claim 1, wherein 0.01≤Bi≤0.45.

10. The paste in claim 1, wherein 0.01≤Bi≤0.35.

11. The paste in claim 1, wherein 0.01≤Bi≤0.25.

12. The paste in claim 1, wherein 0.01≤Bi≤0.15.

13. The paste in claim 1, wherein 0.01≤Bi≤0.05.

14. The paste of claim 1, wherein the frit comprises a bismuth-born-metal-oxygen composition of
$$[ {{Bi}_{x} ( {B}_{y} {M}_{z} {{M}_{{z}^{′}}^{′} ( {M}_{{z}^{i}}^{i} )}_{( 1 - x )} ]}^{{n}^{+}} {O}_{\frac{{n}^{+}}{2}} , \qquad$$
wherein 0<z≤0.7 and z is the mole fraction of metal (M) cations based on the total number of moles of bismuth, boron and metal cations, respectively, selected from one of Li, Na, K, Rb, Cs, Mg, Ca, Sr, Ba, Al, Si, P, Sc, Ti, V, Cr, Mn, Fe, Co, Ni, Cu, Zn, Ga, Ge, Y, Zr, Nb, Mo, Ru, Pd, Ag, In, Sn, Sb, Te, Hf, Ta, W, Pt, Au, Tl, Pb, La and the other lanthanide elements and mixtures thereof, wherein the metal cations comprise oxides, halides or fluorides.

15. The paste of claim 1, wherein inorganic frit system comprises metal cations including one of oxides, halides and fluorides.

16. The paste of claim 1, wherein the inorganic frit system comprises 0.3 to 10 weight percent based on a total amount of solids of the paste.

17. The paste of claim 2, further comprising a silver content from 75 to 99.5 weight percent based on a total amount of solids in the paste.

18. The paste of claim 1, wherein the inorganic frit system includes more than one inorganic frit.

19. The paste of claim 1, wherein the inorganic frit system in lead free.

20. The paste of claim 1, further comprising an organic medium including one of an organic vehicle and additive.

21. The paste of claim 1, wherein the paste is a busbar paste.

22. A dual-print screen-print process comprising the paste of claim 1.

23. A photovoltaic cell comprising the paste of claim 1.

24. A photovoltaic cell comprising the paste of claim 1 wherein the photovoltaic cell further comprises an emitter surface that is lightly doped with high sheet resistance and passivated with an oxide layer.

25. A photovoltaic cell comprising the paste of claim 1 wherein the photovoltaic cell further comprises passivated emitter rear (PERC cell).

26. A photovoltaic cell comprising the paste of claim 1 wherein the photovoltaic cell further is a photovoltaic PERC cell with selective emitter (PERC-SE cell).

27. The paste of claim 1, where is paste does not contact the emitter layer of the photovoltaic cell.

28. A photovoltaic module comprising the photovoltaic cell of claim 20.
